(19) United States
(12) Patent Application Publication
(10) Pub. No.: US 2025/0267993 A1
(43) Pub. Date: Aug. 21, 2025

(54) DISPLAY DEVICE

(71) Applicant: LG Display Co., Ltd., Seoul (KR)

(72) Inventors: Injun LEE, Gimpo-si (KR); HaeYoon JUNG, Seoul (KR); Hyokang LEE, Seoul (KR); Aesun KIM, Seoul (KR); MyungSub LIM, Seoul (KR); YuRa JEONG, Seoul (KR)

(73) Assignee: LG Display Co., Ltd., Seoul (KR)

(21) Appl. No.: 18/894,742

(22) Filed: Sep. 24, 2024

(30) Foreign Application Priority Data
Feb. 20, 2024 (KR) 10-2024-0024192

(51) Int. Cl. H01L 33/60; H01L 25/16; H01L 33/50

(52) U.S. Cl. CPC H10H 20/856; H01L 25/167; H10H 20/8515

(57) ABSTRACT

A display device in one example includes a lower substrate having a plurality of rigid areas disposed to be spaced apart from each other and a malleable area enclosing the plurality of rigid areas, a plurality of first plate patterns disposed in the plurality of rigid areas of the lower substrate, and a plurality of first sub pixels partially disposed on the plurality of first plate patterns. Each of the plurality of first sub pixels includes a first light emitting diode, a light conversion layer facing one side surface of the first light emitting diode, and a first reflective layer facing an opposite surface of one side surface of the first light emitting diode.

### CROSS-REFERENCE TO RELATED APPLICATIONS

This application claims priority to Korean Patent Application No. 10-2024-0024192 filed on Feb. 20, 2024, in the Korean Intellectual Property Office, the entire contents of which is hereby expressly incorporated by reference into the present application.

### BACKGROUND

### Field

The present disclosure relates to a display device, and more particularly to a stretchable display device which can be stretched.

### Discussion of the Related Art

Display devices can be used for a monitor of a computer, a television, or a cellular phone. Among such display devices, there are an organic light emitting display device (OLED) which is a self-emitting device, a liquid crystal display device (LCD) which requires a separate light source, and the like.

An applicable range of the display device is diversified to personal digital assistants as well as monitors of computers and televisions. A display device with a large display area and a reduced volume and weight is being studied.

Further, a display device is manufactured by forming a display unit, a wiring line, and the like on a flexible substrate made of a flexible material such as plastic. This renders the display device to be stretchable in a specific direction and changed in various forms, which is getting attention as a next generation display device.

### SUMMARY OF THE DISCLOSURE

An object to be achieved by the present disclosure is to provide a display device with an improved efficiency of red light.

Another object to be achieved by the present disclosure is to provide a display device with an improved light conversion efficiency of a red light conversion layer.

Still another object to be achieved by the present disclosure is to provide a display device which improves a light conversion efficiency by forming a light conversion layer to have a long length.

Still another object to be achieved by the present disclosure is to provide a display device in which a light emitting diode and a light conversion layer are formed together in a rigid area.

Still another object to be achieved by the present disclosure is to provide a display device in which a light emitting diode is formed in a rigid area and a light conversion layer is formed in a malleable area.

Still another object to be achieved by the present disclosure is to provide a display device in which a light conversion layer is formed on a connection line.

Still another object to be achieved by the present disclosure is to provide a display device in which a light emitting diode and a light conversion layer are formed together on a connection line.

Still another object to be achieved by the present disclosure is to provide a display device in which a step between a light conversion layer of a malleable area and a light emitting diode of a rigid area is minimized.

Objects of the present disclosure are not limited to the above-mentioned objects, and other objects, which are not mentioned above, can be clearly understood by those skilled in the art from the following descriptions.

According to an aspect of the present disclosure, a display device includes a lower substrate having a plurality of rigid areas disposed to be spaced apart from each other and a malleable area enclosing the plurality of rigid areas; a plurality of first plate patterns disposed in the plurality of rigid areas of the lower substrate; and a plurality of first sub pixels partially disposed on the plurality of first plate patterns, wherein each of the plurality of first sub pixels includes: a first light emitting diode, a light conversion layer disposed opposite to one side surface of the first light emitting diode, and a first reflective layer disposed opposite to an opposite surface of one side surface of the first light emitting diode. Accordingly, light from the first light emitting diode is reflected to the light conversion layer disposed on a side portion of the first light emitting diode using the first reflective layer to improve a light conversion efficiency of the light conversion layer.

Other detailed matters of the example embodiments are included in the detailed description and the drawings.

A display device according to one or more aspects of the present disclosure can improve an efficiency of red light.

A display device according to one or more aspects of the present disclosure can improve a light conversion efficiency of a red light conversion layer.

A display device according to one or more aspects of the present disclosure can improve a light conversion efficiency by forming a light conversion layer to have a long length, instead of a thickness of the light conversion layer.

A display device according to one or more aspects of the present disclosure can form a light emitting diode and a light conversion layer together in a rigid area.

A display device according to one or more aspects of the present disclosure can form a light emitting diode in a rigid area and a light conversion layer in a malleable area.

A display device according to one or more aspects of the present disclosure can form a light conversion layer on a connection line.

A display device according to one or more aspects of the present disclosure can form a light emitting diode and a light conversion layer together on a connection line.

A display device according to one or more aspects of the present disclosure can minimize a step between a light emitting diode of a malleable area and a light conversion layer in a rigid area.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an example embodiment of the present disclosure;

FIG. 2 is an enlarged plan view of an active area of a display device according to an example embodiment of the present disclosure;

FIG. 3 is a cross-sectional view of a first sub pixel of a display device according to an example embodiment of the present disclosure;

FIG. 4 is a cross-sectional view of a second sub pixel of a display device according to an example embodiment of the present disclosure;

FIG. 5 is a cross-sectional view of a third sub pixel of a display device according to an example embodiment of the present disclosure;

FIG. 6 is an enlarged plan view of an active area of a display device according to another example embodiment of the present disclosure;

FIG. 7 is a cross-sectional view of a first sub pixel of a display device according to another example embodiment of the present disclosure;

FIG. 8 is an enlarged plan view of an active area of a display device according to still another example embodiment of the present disclosure;

FIG. 9 is a cross-sectional view of a first sub pixel of a display device according to still another example embodiment of the present disclosure;

FIG. 10 is an enlarged plan view of an active area of a display device according to still another example embodiment of the present disclosure; and

FIG. 11 is a cross-sectional view of a first sub pixel of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, one or more additional different layers or elements can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings. All the components of each display device according to all embodiments of the present disclosure are operatively coupled and configured.

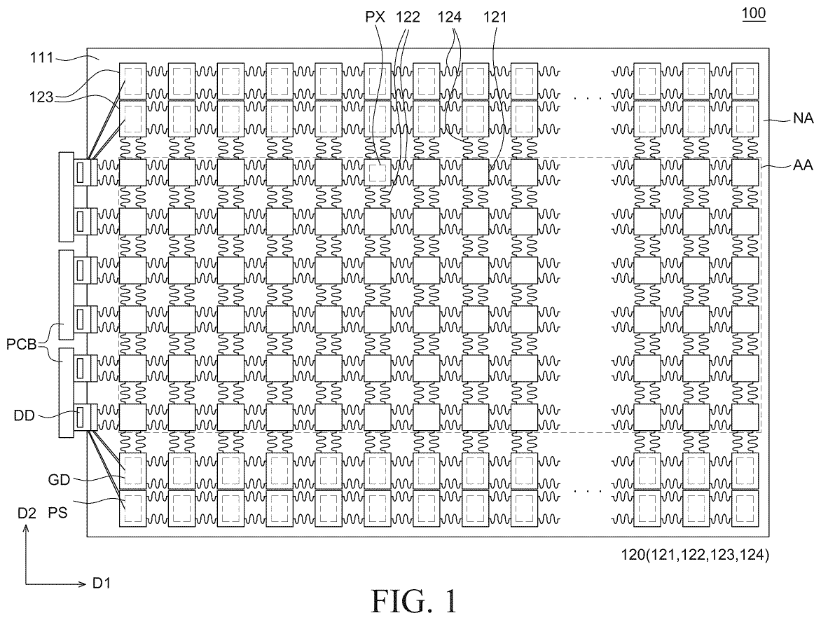

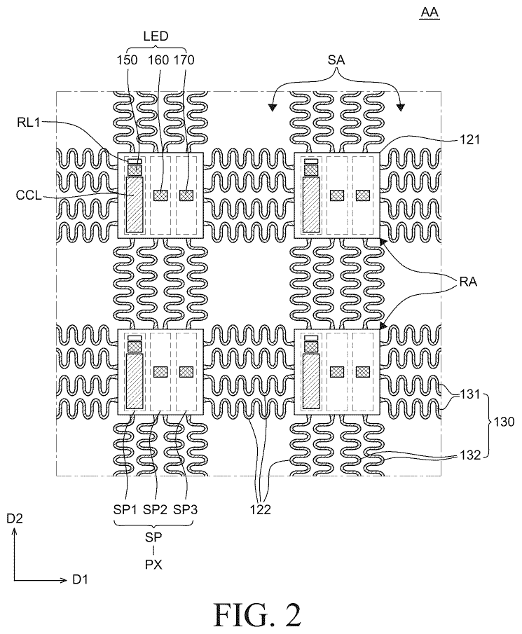

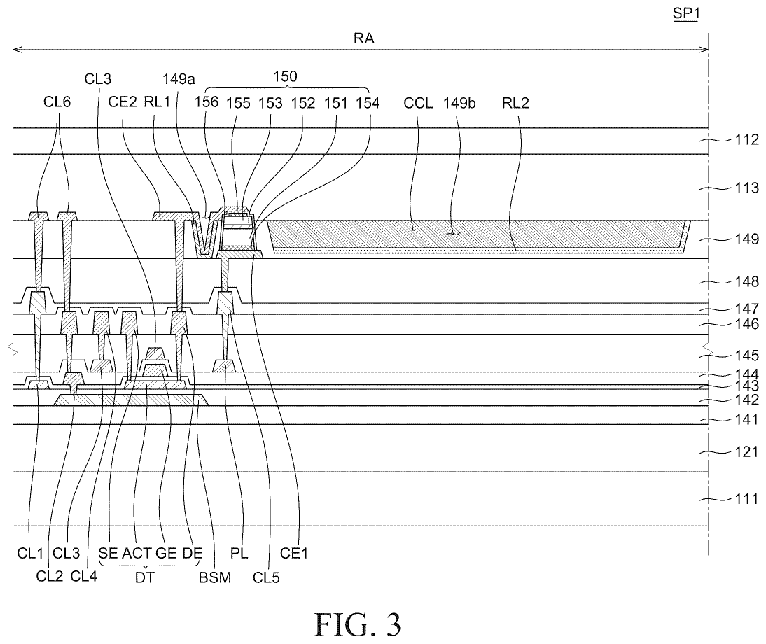

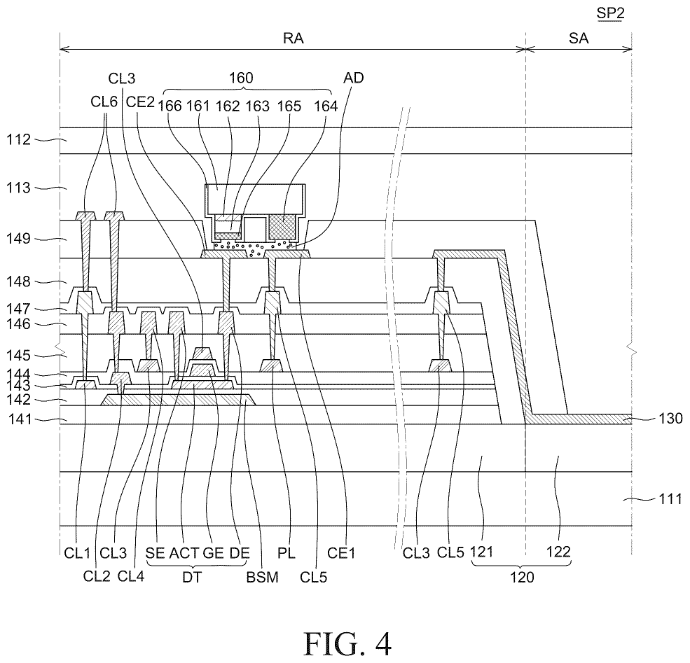

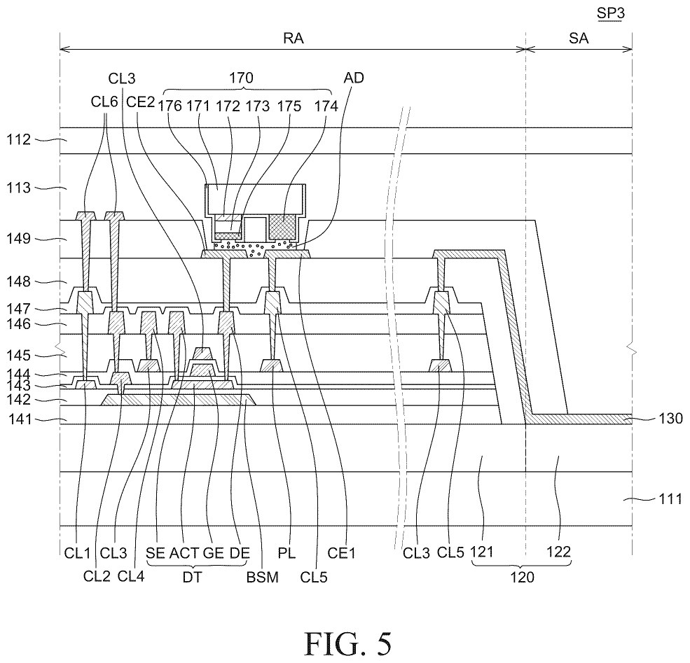

FIG. 1 is a plan view of a display device according to an example embodiment of the present disclosure. FIG. 2 is an enlarged plan view of an active area of a display device according to an example embodiment of the present disclosure. FIG. 3 is a cross-sectional view of a first sub pixel of a display device according to an example embodiment of the present disclosure. FIG. 4 is a cross-sectional view of a second sub pixel of a display device according to an example embodiment of the present disclosure. FIG. 5 is a cross-sectional view of a third sub pixel of a display device according to an example embodiment of the present disclosure. In FIG. 2, for the convenience of description, among configurations of a plurality of sub pixels disposed on a first plate pattern 121, a first reflection layer RL1, a light emitting diode LED, and a light conversion layer CCL are illustrated.

First, a display device 100 according to an example embodiment of the present disclosure is a display device 100 which is capable of displaying images even in a bent or extended state and can also be referred to as a stretchable display device 100, a flexible display device 100, and an extendable display device 100. As compared with the general display devices of the related art, the display device 100 can have not only a high flexibility, but also stretchability. Therefore, the user can bend or extend a display device 100 and a shape of a display device 100 can be freely changed in accordance with manipulation of a user. For example, when the user pulls the display device 100 by holding ends of the display device, the display device 100 can be extended to the pulling direction of the user. Alternatively, when the user disposes the display device 100 on an outer surface which is not flat, the display device 100 can be disposed to be bent in accordance with the shape of the outer surface. Further, when a force applied by the user is removed, the display device 100 can return to its original shape.

Referring to FIGS. 1 to 4 together, the lower substrate 111 is a substrate which supports and protects several components of the display device 100. The lower substrate 111 can support a pattern layer 120 on which the pixels PX, the gate driver GD, and the power supply PS are formed.

An upper substrate 112 is a substrate which covers and protects several components of the display device 100. The upper substrate 112 can cover the pixels PX, the gate driver GD, and the power supply PS.

The lower substrate 111 and the upper substrate 112 which are flexible substrates can be configured by an insulating material which is bendable or extendable. For example, the lower substrate 111 and the upper substrate 112 can be formed of a silicon rubber such as polydimethylsiloxane (PDMS) or an elastomer such as polyurethane (PU) and polytetrafluoroethylene (PTFE) and thus have a flexibility. Further, the materials of the lower substrate 111 and the upper substrate 112 can be the same, but are not limited thereto and can vary.

The lower substrate 111 and the upper substrate 112 are flexible substrates so as to be reversibly expandable and contractible. Accordingly, the lower substrate 111 can be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, a first flexible substrate, or the like. The upper substrate 112 can be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, a second flexible substrate, or the like.

Moduli of elasticity of the lower substrate 111 and the upper substrate 112 can be several MPa to several hundreds of MPa. Further, a ductile breaking rate of the lower substrate 111 and the upper substrate 112 can be 100% or higher. Here, the ductile breaking rate refers to a stretching rate at a timing when an object to be stretched is broken or cracked. A thickness of the lower substrate 111 can be 10 μm to 1 mm, but is not limited thereto.

The lower substrate 111 includes an active area AA and a non-active area NA enclosing the active area AA. However, the active area AA and the non-active area NA are not mentioned to be limited to the lower substrate 111, but mentioned for the entire display device 100.

The active area AA is an area in which images are displayed in the display device 100 and a plurality of pixels PX is disposed in the active area AA. Further, each pixel PX can include a display element and various driving elements for driving the display element. Various driving elements can refer to at least one thin film transistor (TFT) and a capacitor, but are not limited thereto. The plurality of pixels PX can be connected to various wiring lines to be driven, respectively. For example, each of the plurality of pixels PX can be connected to various wiring lines, such as a scan line, a data line, a high potential voltage line, a low potential voltage line, a reference voltage line, and an initialization voltage line.

The non-active area NA is an area where no image is displayed. The non-active area NA can be an area adjacent to the active area AA. Further, the non-active area NA can be adjacent to the active area AA to enclose the active area AA. However, it is not limited thereto so that the non-active area NA corresponds to an area excluding the active area AA from the lower substrate 111 and can be modified and separated in various forms. In the non-active area NA, components for driving a plurality of pixels PX disposed in the active area AA, such as a gate driver GD and a power supply PS, can be disposed. Further, in the non-active area NA, a plurality of pads connected to the data driver DD and the printed circuit board PCB can be disposed and each pad can be connected to each of the plurality of pixels PX of the active area AA.

A filling layer 113 is disposed between the lower substrate 111 and the upper substrate 112. The filling layer 113 can be fully filled in an empty space between the lower substrate 111 and the upper substrate 112. For example, the filling layer 113 can be configured by a curable adhesive. Specifically, the material which configures the filling layer 113 is coated on the entire surface of the lower substrate 111 and then is cured so that the filling layer 113 can be disposed between the components disposed on the upper substrate 112 and the lower substrate 111. For example, the filling layer 113 can be an optically clear adhesive (OCA) and can be configured by an acrylic-based adhesive, a silicon-based adhesive, and a urethane-based adhesive.

The pattern layer 120 is disposed on the lower substrate 111. The pattern layer 120 includes a plurality of first plate patterns 121 and a plurality of first line patterns 122 disposed in the active area AA and a plurality of second plate patterns 123 and a plurality of second line patterns 124 disposed in the non-active area NA.

A plurality of plate patterns is disposed in the active area AA and the non-active area NA. The plurality of plate patterns includes a plurality of first plate patterns 121 and a plurality of second plate patterns 123. The plurality of first plate patterns 121 is disposed in the active area AA of the lower substrate 111 and the plurality of second plate patterns 123 is disposed in the non-active area NA of the lower substrate 111. On the plurality of first plate patterns 121, a plurality of pixels PX is formed and on the plurality of second plate patterns 123, a gate driver GD and a power supply PS can be formed.

The plurality of first plate patterns 121 and the plurality of second plate patterns 123 can be disposed in the form of separate islands. The plurality of first plate patterns 121 and the plurality of second plate patterns 123 can be individually separated. Therefore, the plurality of first plate patterns 121 and the plurality of second plate patterns 123 can be referred to as first island patterns and second island patterns or first individual patterns and second individual patterns.

A size of each of the plurality of second plate patterns 123 can be larger than a size of each of the plurality of first plate patterns 121. In each of the plurality of second plate patterns 123, one stage of the gate driver GD can be disposed. Therefore, an area occupied by various circuit configurations which configure one stage of the gate driver GD can be relatively larger than an area occupied by one pixel PX so that a size of each of the plurality of second plate patterns 123 can be larger than a size of each of the plurality of first plate patterns 121.

In the meantime, even though it is illustrated in FIG. 1 that the plurality of second plate patterns 123 is disposed in the non-active area NA on both sides of the active area AA in the second direction D2, this is illustrative so that the plurality of second plate patterns 123 can be disposed in an arbitrary area of the non-active area NA. Further, even though it is illustrated that the plurality of first plate patterns 121 and the plurality of second plate patterns 123 have a rectangular shape, it is not limited thereto and the shapes of the plurality of first plate patterns 121 and the plurality of second plate patterns 123 can vary in various forms.

Referring to FIGS. 1 and 2, the plurality of line patterns is disposed in the active area AA and the non-active area NA. The plurality of line patterns includes a plurality of first line patterns 122 and a plurality of second line patterns 124.

The plurality of first line patterns 122 is disposed in the active area AA. The plurality of first line patterns 122 is patterns which connect first plate patterns 121 which are adjacent to each other and can be referred to as internal connection patterns. For example, the plurality of first line patterns 122 can be disposed between the plurality of first plate patterns 121.

The plurality of second line patterns 124 of the pattern layer 120 is disposed in the non-active area NA. The plurality of second line patterns 124 connects the first plate pattern 121 and the second plate pattern 123 which are adjacent to each other or connects a plurality of adjacent second plate patterns 123 and can be referred to as external connection patterns. The plurality of second line patterns 124 can be disposed between the first plate pattern 121 and the second plate pattern 123 which are adjacent to each other and between the plurality of second plate patterns 123 which is adjacent to each other.

The plurality of first line patterns 122 and the plurality of second line patterns 124 have a wavy shape. For example, the plurality of first line patterns 122 and the plurality of second line patterns 124 can have a sinusoidal shape. However, the shape of the plurality of first line patterns 122 and the plurality of second line patterns 124 is not limited thereto. For example, the plurality of first line patterns 122 and the plurality of second line patterns 124 can extend in a zigzag pattern. Further, the plurality of first line patterns 122 and the plurality of second line patterns 124 can have various shapes such as a shape in which a plurality of rhombic substrates is connected at their vertexes to be extended or a shape in which semi-circular and quadrant-shaped substrates are connected to each other. Further, the number and the shape of the plurality of first line patterns 122 and the plurality of second line patterns 124 illustrated in FIG. 1 are illustrative and can be changed in various forms depending on the design.

In the meantime, the plurality of first plate patterns 121, the plurality of first line patterns 122, the plurality of second plate patterns 123, and the plurality of second line patterns 124 are rigid patterns. For example, the plurality of first plate patterns 121, the plurality of first line patterns 122, the plurality of second plate patterns 123, and the plurality of second line patterns 124 can be more rigid than the lower substrate 111 and the upper substrate 112.

The plurality of first plate patterns 121, the plurality of first line patterns 122, the plurality of second plate patterns 123, and the plurality of second line patterns 124 which are rigid substrates can be formed of a plastic material having a lower flexibility than the lower substrate 111 and the upper substrate 112. For example, the plurality of first plate patterns 121, the plurality of first line patterns 122, the plurality of second plate patterns 123, and the plurality of second line patterns 124 can be formed of at least one material of polyimide (PI), polyacrylate, and polyacetate. At this time, when the plurality of first plate patterns 121, the plurality of first line patterns 122, the plurality of second plate patterns 123, and the plurality of second line patterns 124 are formed of the same material, the plurality of first plate patterns 121, the plurality of first line patterns 122, the plurality of second plate patterns 123, and the plurality of second line patterns 124 are integrally formed. However, when the plurality of first plate patterns 121, the plurality of first line patterns 122, the plurality of second plate patterns 123, and the plurality of second line patterns 124 can be formed of different materials, but are not limited thereto.

Moduli of elasticity of the plurality of first plate patterns 121, the plurality of first line patterns 122, the plurality of second plate patterns 123, and the plurality of second line patterns 124 can be higher than a modulus of elasticity of the lower substrate 111. The modulus of elasticity is a parameter representing a rate of deformation against the stress applied to the substrate and the higher the modulus of elasticity, the higher the hardness. Therefore, the plurality of first plate patterns 121, the plurality of first line patterns 122, the plurality of second plate patterns 123, and the plurality of second line patterns 124 can be referred to as a plurality of first rigid patterns, a plurality of second rigid patterns, a plurality of third rigid patterns, and a plurality of fourth rigid patterns, respectively. Moduli of elasticity of the plurality of first plate patterns 121, the plurality of first line patterns 122, the plurality of second plate patterns 123, and the plurality of second line patterns 124 can be 1000 times or higher than the moduli of elasticity of the lower substrate 111 and the upper substrate 112, but it is not limited thereto.

In the meantime, in some example embodiments, the lower substrate 111 can be defined to include a plurality of rigid areas RA and malleable areas SA. The plurality of rigid areas RA can be disposed to be spaced apart from each other. The plurality of rigid areas RA can be areas of the lower substrate 111 overlapping the plurality of first plate patterns 121 and the plurality of second plate patterns 123. The plurality of rigid areas RA can be areas in which the plurality of first plate patterns 121 and the plurality of second plate patterns 123 are disposed to have a rigid characteristic. The malleable area SA can be an area which encloses each of the plurality of rigid areas RA. The malleable area SA can be an area which does not overlap the plurality of first plate patterns 121 and the plurality of second plate patterns 123. The malleable area SA is an area between the plurality of first plate patterns 121 and the plurality of second plate patterns 123 and can include an area in which the plurality of first line patterns 122 and the plurality of second line patterns 124 are disposed. Further, the malleable area SA can include an area in which the pattern layer 120 is not disposed. The malleable area SA can be an area in which the plurality of first plate patterns 121 and the plurality of second plate patterns 123 are not disposed to be flexibly deformable. In the plurality of rigid areas RA, the plurality of first plate patterns 121 and the plurality of second plate patterns 123 are disposed. In the malleable area SA, the plurality of first plate patterns 121 and the plurality of second plate patterns 123 are not disposed. Therefore, the plurality of rigid areas RA can be more rigid than the malleable area SA. At this time, the malleable area SA and the plurality of rigid areas RA are not mentioned to be limited to the lower substrate 111, but mentioned for the entire display device 100.

Further, in some example embodiments, the lower substrate 111 can be defined to include a plurality of first lower patterns and a second lower pattern. The plurality of first lower patterns can be an area of the lower substrate 111 overlapping the plurality of first plate patterns 121 and the plurality of second plate patterns 123. The second lower pattern can be a remaining area which does not overlap the plurality of first plate patterns 121 and the plurality of second plate patterns 123.

Furthermore, the upper substrate 112 can be defined to include a plurality of first upper patterns and a second upper pattern. The plurality of first upper patterns can be an area overlapping the plurality of the first plate patterns 121 and the plurality of second plate patterns 123 of the upper substrate 112, but the second upper pattern can be a remaining area which does not overlap the plurality of the first plate patterns 121 and the plurality of second plate patterns 123.

At this time, moduli of elasticity of the plurality of first lower patterns and the first upper pattern can be higher than moduli of elasticity of the second lower pattern and the second upper pattern. For example, the plurality of first lower patterns and the first upper pattern can be formed of the same material as the plurality of first plate patterns 121 and the plurality of second plate patterns 123. The second lower pattern and the second upper pattern can be formed of a material having a modulus of elasticity lower than those of the plurality of first plate patterns 121 and the plurality of second plate patterns 123.

For example, the first lower pattern and the first upper pattern can be formed of polyimide (PI), polyacrylate, polyacetate, or the like. Further, the second lower pattern and the second upper pattern can be formed of silicon rubber such as polydimethylsiloxane (PDMS) or elastomer such as polyurethane (PU) or polytetrafluoroethylene.

The gate driver GD can be mounted on the plurality of second plate patterns 123. The gate driver GD can be formed on the plurality of second plate patterns 123 in a gate in panel (GIP) manner when various elements on the plurality of first plate patterns 121 are manufactured. Therefore, various circuit configurations which configure the gate driver GD, such as transistors, capacitors, and wiring lines, can be disposed on the plurality of second plate patterns 123. One stage which is a circuit which configures the gate driver GD and includes transistors and capacitors can be disposed above each of the plurality of second plate patterns 123. However, the gate driver GD can be mounted in a chip on film (COF) manner, but is not limited thereto.

A power supply PS can be disposed on the plurality of second plate patterns 123. The power supply PS can be formed on the second plate pattern 123 adjacent to the gate driver GD. The power supply PS is a plurality of power blocks patterned when various components on the first plate pattern 121 is manufactured and can be formed on the second plate pattern 123. The power supply PS is electrically connected to the gate driver GD of the non-active area NA and the plurality of pixels PX of the active area AA to supply a driving voltage. Specifically, the power supply PS can be electrically connected to the gate driver GD formed on the second plate pattern 123 and the plurality of pixels PX formed on the first plate pattern 121 by means of the second line pattern 124 and the first line pattern 122. For example, the power supply PS can supply a gate driving voltage and a clock signal to the gate driver GD. Further, the power supply PS can supply the power voltage to each of the plurality of pixels PX.

The printed circuit board PCB is connected to an edge of the lower substrate 111. The printed circuit board PCB is a component which transmits signals and voltages for driving the display element from the control unit to the display element. Therefore, the printed circuit board PCB can also be referred to as a driving substrate. A controller, such as an IC chip or a circuit unit, can be mounted on the printed circuit board PCB. Further, on the printed circuit board PCB, a memory, a processor, or the like, can also be mounted. Further, the printed circuit board PCB provided in the display device 100 can include a stretching area and a non-stretching area to ensure stretchability. Further, in the non-stretching area, an IC chip, a circuit unit, a memory, a processor, and the like can be mounted. In the stretching area, wiring lines which are electrically connected to the IC chip, the circuit unit, the memory, and the processor can be disposed.

The data driver DD is a component which supplies a data voltage to the plurality of pixels PX disposed in the active area AA. The data driver DD is configured as an IC chip so that it can be also referred to as a data integrated circuit D-IC. Further, the data driver DD can be mounted in the non-stretching area of the printed circuit board PCB. For example, the data driver DD can be mounted on the printed circuit board PCB in the form of a chip on board (COB). However, even though in FIG. 1, it is illustrated that the data driver DD is mounted in a COB manner, the data driver DD can be mounted in a chip on film (COF), a chip on glass (COG), or a tape carrier package (TCP) manner, but it is not limited thereto.

Further, even though in FIG. 1, one data driver DD is disposed so as to correspond to each of a plurality of columns formed by the plurality of first plate patterns 121 disposed in the active area AA, it is not limited thereto. For example, one data driver DD can be disposed so as to correspond to a plurality of columns formed by a plurality of first plate patterns 121.

Referring to FIGS. 1 and 2, the plurality of first plate patterns 121 is disposed in the active area AA of the lower substrate 111. The plurality of first plate patterns 121 can be disposed to be spaced apart from each other. For example, the plurality of first plate patterns 121 can be disposed in a plurality of rows and a plurality of columns to be disposed in a matrix. For example, the plurality of first plate patterns 121 is disposed to be spaced apart from each other with a predetermined interval in the first direction D1. The plurality of first plate patterns 121 can be disposed to be spaced apart from each other with a predetermined interval in the second direction D2.

The plurality of first line patterns 122 can be disposed in the active area AA of the lower substrate 111. The plurality of first line patterns 122 is disposed in an area between the plurality of first plate patterns 121 to connect the plurality of first plate patterns 121. The plurality of first line patterns 122 extends in the first direction D1 or the second direction D2 and can connect the first plate patterns 121 which are adjacent to each other in the first direction D1 or the second direction D2. For example, some first line patterns extending in the first direction D1, among the plurality of first line patterns 122, can connect one pair of first plate patterns 121 which are adjacent to each other in the first direction D1. The remaining first line patterns 122 extending in the second direction D2, among the plurality of first line patterns 122, can connect one pair of first plate patterns 121 which are adjacent to each other in the second direction D2.

In the meantime, an adhesive layer can be further disposed between the pattern layer 120 and the lower substrate 111. The adhesive layer is a layer for bonding the lower substrate 111 and the pattern layer 120. When the display device 100 is formed, after sequentially forming configurations of the pattern layer 120 and the plurality of sub pixels SP on a rigid substrate, the rigid substrate and the pattern layer 120 are separated and the lower substrate 111 can be attached below the pattern layer 120. At this time, in order to fix the pattern layer 120 and the lower substrate 111, the adhesive layer can be disposed between the pattern layer 120 and the lower substrate 111. For example, the adhesive layer can be an optically clear adhesive (OCA), but is not limited thereto.

Next, a pixel PX including the plurality of sub pixels SP which is an individual unit to emit light is disposed in the plurality of first plate patterns 121. The plurality of sub pixels SP can form one pixel PX. N sub pixels SP which form one pixel PX can be disposed in each of the plurality of first plate patterns 121. The plurality of sub pixels SP can include a first sub pixel SP1, a second sub pixel SP2, and a third sub pixel SP3. The first sub pixel SP1 is a red sub pixel SP, a second sub pixel SP2 is a green sub pixel SP, and a third sub pixel SP3 can be a blue sub pixel SP.

In the meantime, it is illustrated that one pixel PX includes three sub pixels SP. However, as a variation, the plurality of sub pixels SP can further include a white sub pixel depending on a design of the display device and the number and a configuration of the plurality of sub pixels SP which forms one pixel PX are not limited thereto.

Each of the plurality of sub pixels SP includes a light emitting diode LED which is a display element and a pixel circuit for driving the light emitting diode LED.

The light emitting diode LED can be configured by any one of various elements depending on a type of the display device 100. For example, when the display device 100 is an organic light emitting display device, the light emitting diode LED can be an organic light emitting diode and when the display device 100 is an inorganic light emitting display device, the light emitting diode LED can be a light emitting diode LED or a micro LED. Hereinafter, it is assumed that the light emitting diode LED is a micro LED, but it is not limited thereto.

The pixel circuit supplies the driving current to the light emitting diode LED to allow the light emitting diode LED to emit light. The pixel circuit can include a plurality of transistors and capacitors. For example, the pixel circuit can include a plurality of transistors, such as a driving transistor DT or a switching transistor and a capacitor which is connected to any one of the plurality of transistors.

Hereinafter, the plurality of sub pixels SP of the display device according to aspects of the present disclosure will now be described in more detail with reference to FIGS. 2 to 5.

Referring to FIGS. 2 to 5, a plurality of inorganic insulating layers is disposed on the plurality of first plate patterns 121. For example, the plurality of inorganic insulating layers can include a multi-buffer layer 141, an active buffer layer 142, a gate insulating layer 143, a first interlayer insulating layer 144, a second interlayer insulating layer 145, a third interlayer insulating layer 146, and a passivation layer 147. However, in addition to the above-described inorganic insulating layers, another inorganic insulating layer can be additionally disposed or one or more of the above-described inorganic insulating layers can be omitted. A configuration of the plurality of inorganic insulating layers is not limited thereto.

First, the multi-buffer layer 141 is disposed on the plurality of first plate patterns 121 and the active buffer layer 142 is disposed on the multi-buffer layer 141. The multi-buffer layer 141 and the active buffer layer 142 reduce the permeation of moisture or impurities from the outside of the lower substrate 111 and the first plate pattern 121. The multi-buffer layer 141 and the active buffer layer 142 can protect various components of the display device 100 from the moisture and oxygen of the outside. The multi-buffer layer 141 and the active buffer layer 142 can be formed of an insulating material. For example, the multi-buffer layer 141 and the active buffer layer 142 are configured by a single layer or a double layer of silicon nitride (SiNx), silicon oxide (SiOx), and silicon oxynitride (SiON), but are not limited thereto. However, the multi-buffer layer 141 and the active buffer layer 142 can be omitted depending on a structure or a characteristic of the display device 100.

In the meantime, the multi-buffer layer 141 and the active buffer layer 142 can be formed only above the plurality of first plate patterns 121 and the plurality of second plate patterns 123. The multi-buffer layer 141 and the active buffer layer 142 can overlap the area in which the first plate patterns 121 and the second plate patterns 123 are disposed. The multi-buffer layer 141 and the active buffer layer 142 may not be formed in an area between the plurality of first plate patterns 121 and an area between the plurality of second plate patterns 123. The multi-buffer layer 141 and the active buffer layer 142 which are formed of an inorganic material can be easily cracked to be damaged during a process of stretching the display device 100. Therefore, the multi-buffer layer 141 and the active buffer layer 142 are patterned to have a shape of the plurality of first plate patterns 121 and the plurality of second plate patterns 123 to be formed only above the plurality of first plate patterns 121 and the plurality of second plate patterns 123. Accordingly, in the display device 100 according to the example embodiment of the present disclosure, the multi-buffer layer 141 and the active buffer layer 142 are formed only in an area overlapping the plurality of first plate patterns 121 and the plurality of second plate patterns 123 which are rigid patterns. Therefore, even though the display device 100 is bent or stretched to be deformed, the damage of the multi-buffer layer 141 and the active buffer layer 142 is suppressed so that the damages of various components of the display device 100 can also be suppressed.

A light shielding layer BSM is disposed between the multi-buffer layer 141 and the active buffer layer 142. The light shielding layer BSM blocks light which is incident onto the active layer ACT of a transistor to be described below, below the substrate. Light which is incident onto the active layer ACT of the driving transistor DT is blocked by the light shielding layer BSM to minimize a leakage current. The light shielding layer BSM can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

A driving transistor DT is disposed on the active buffer layer 142. The driving transistor DT includes an active layer ACT, a gate electrode GE, a source electrode SE, and a drain electrode DE.

First, the active layer ACT is disposed on the active buffer layer 142. The active layer ACT can be formed of a semiconductor material, such as an oxide semiconductor, amorphous silicon, or polysilicon, but is not limited thereto.

The gate insulating layer 143 is disposed on the active layer ACT. The gate insulating layer 143 is an insulating layer which insulates the active layer ACT from the gate electrode GE and can be configured by a single layer or a double layer of silicon oxide (SiOx) or silicon nitride (SiNx), but is not limited thereto.

The gate electrode GE is disposed on the gate insulating layer 143. The gate electrode GE can be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The first interlayer insulating layer 144 is disposed on the gate electrode GE and the second interlayer insulating layer 145 is disposed on the first interlayer insulating layer 144. The first interlayer insulating layer 144 and the second interlayer insulating layer 145 are insulating layers which protect components therebelow and can be configured by a single layer or a double layer of silicon oxide (SiOx) or silicon nitride (SiNx), but are not limited thereto.

The source electrode SE and the drain electrode DE are disposed on the second interlayer insulating layer 145. The source electrode SE and the drain electrode DE can be electrically connected to the active layer ACT through a contact hole formed in the second interlayer insulating layer 145, the first interlayer insulating layer 144, and the gate insulating layer 143. The source electrode SE and the drain electrode DE can be configured by a single layer or a multi-layered structure of a conductive material, such as copper (Cu), aluminum (Al), molybdenum (Mo), nickel (Ni), titanium (Ti), chrome (Cr), or an alloy thereof, but are not limited thereto.

Next, a first conductive layer CL1 is disposed between the active buffer layer 142 and the gate insulating layer 143. The first conductive layers CL1 can configure at least a part of the plurality of wiring lines which supplies various signals to the sub pixel SPX or a configuration of the pixel circuit. For example, the first conductive layer CL1 can be any one of various wiring lines, such as a scan line, a data line, a reference line, an initialization line, a high potential power line, and a low potential power line or can be a configuration included in a transistor or a capacitor. The first conductive layer CL1 can be formed of the same material as the active layer ACT.

A second conductive layers CL2 is disposed between the gate insulating layer 143 and the first interlayer insulating layer 144. The second conductive layer CL2 is an electrode which applies a voltage to the light shielding layer BSM. For example, the light shielding layer BSM is electrically connected to another configuration disposed on the first plate pattern 121 through a second conductive layer CL2 to be applied with a voltage. The light shielding layer BSM which is applied with a voltage by means of the second conductive layer CL2 does not operate as a floating gate and can minimize a fluctuation of a threshold voltage of the driving transistor DT which is generated by the floated light shielding layer BSM. The second conductive layer CL2 can be formed of the same conductive material as the gate electrode GE and can be configured by a single layer or a multi-layered structure of copper (Cu), aluminum (Al), molybdenum (Mo), nickel (Ni), titanium (Ti), gold (Au), chrome (Cr), or an alloy thereof, but is not limited thereto.

The power line PL is disposed between the first interlayer insulating layer 144 and the second interlayer insulating layer 145. The power line PL is a wiring line which transmits a power voltage to the light emitting diode LED. The power line PL can be any one of a high potential power line or a low potential power line. The power line PL can be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

A plurality of third conductive layers CL3 is disposed between the first interlayer insulating layer 144 and the second interlayer insulating layer 145. The plurality of third conductive layers CL3 can configure at least a part of the plurality of wiring lines which supplies various signals to the sub pixel SP or a configuration of the pixel circuit. For example, one third conductive layer CL3, among the plurality of third conductive layers CL3, can overlap the gate electrode GE of the driving transistor DT to form a capacitor. As another example, the other third conductive layer CL3, among the plurality of third conductive layers CL3 can serve as a plurality of wiring lines which transmits a signal to the sub pixel SP. The plurality of third conductive layers CL3 can be formed of the same material on the same layer as the power line PL. The plurality of third conductive layers CL3 can be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

A plurality of fourth conductive layers CL4 is disposed between the second interlayer insulating layer 145 and the third interlayer insulating layer 146. The plurality of fourth conductive layers CL4 can configure at least a part of the plurality of wiring lines which supplies various signals to the sub pixel SP or a configuration of the pixel circuit. The plurality of fourth conductive layers CL4 connects wiring lines disposed on different layers and can serve as a part of the wiring line. For example, some of the plurality of fourth conductive layers CL4 can electrically connect the second conductive layer CL2 and a sixth conductive layer CL6 and the others of the plurality of fourth conductive layers CL4 can be electrically connected to the third conductive layer CL3. The plurality of fourth conductive layers CL4 can be formed on the same layer with the same material as the source electrode SE and the drain electrode DE of the driving transistor DT. For example, the plurality of fourth conductive layers CL4 can be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The third interlayer insulating layer 146 is disposed on the plurality of fourth conductive layers CL4. The third interlayer insulating layer 146 is an insulating layer which protects components below the third interlayer insulating layer 146 and can be configured by a single layer or a double layer of silicon oxide (SiOx) or silicon nitride (SiNx), but is not limited thereto.

A plurality of fifth conductive layers CL5 is disposed on the third interlayer insulating layer 146. The plurality of fifth conductive layers CL5 can configure at least a part of the plurality of wiring lines which supplies various signals to the sub pixel SP or a configuration of the pixel circuit. The plurality of fifth conductive layers CL5 connects wiring lines disposed on different layers and can serve as a part of the wiring line. For example, a part of the plurality of fifth conductive layers CL5 can electrically connect the first conductive layer CL1 and the sixth conductive layer CL6. Further, the other fifth conductive layers CL5, among the plurality of fifth conductive layers CL5 can electrically connect the power line PL and the first connection electrode CE1. The plurality of fifth conductive layers CL5 can be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The passivation layer 147 is disposed on the plurality of fifth conductive layers CL5. The passivation layer 147 is an insulating layer which protects components below the passivation layer 147 and can be configured by a single layer or a double layer of silicon oxide (SiOx) or silicon nitride (SiNx), but is not limited thereto.

A first planarization layer 148 is disposed on the passivation layer 147. The first planarization layer 148 can planarize an upper portion of the first plate pattern 121 on which a plurality of conductive layers, a driving transistor DT, and a plurality of wiring lines are disposed. The first planarization layer 148 can be configured by a single layer or a plurality of layers and can be formed of an organic material. For example, the first planarization layer 148 can be configured by a single layer or a double layer, and for example, can be formed of photoresist or an acrylic-based organic material, but is not limited thereto.

Referring to FIGS. 3 to 5, the first connection electrode CE1 is disposed on the first planarization layer 148 in each of the plurality of sub pixels SP. The first connection electrode CE1 is an electrode which electrically connects the light emitting element LED and the power line PL. The first connection electrode CE1 can be electrically connected to the power line PL through the fifth conductive layer CL5. Further, the electrode of the light emitting diode LED can be electrically connected to the first connection electrode CE1. The first connection electrode CE1 can be configured by a single layer or a multi-layered structure of an opaque conductive material, such as copper (Cu), aluminum (Al), molybdenum (Mo), nickel (Ni), titanium (Ti), gold (Au), chrome (Cr), or an alloy thereof, but is not limited thereto.

In the first sub pixel SP1, the first light emitting diode 150 is disposed on the first connection electrode CE1. The first light emitting diode 150 is an element which emits light by a current and can be a light emitting diode (LED) or a micro LED, but is not limited thereto. At this time, the first light emitting diode 150 disposed in the first sub pixel SP1 which is a red sub pixel SP can be a blue light emitting diode or a green light emitting diode. Further, a red light conversion layer CCL is further disposed in the first sub pixel SP1 to convert light emitted from the first light emitting diode into red light to emit the converted red light.

The first light emitting diode 150 includes a first n-type semiconductor layer 151, a first emission layer 152, a first p-type semiconductor layer 153, a first n-type electrode 154, a first p-type electrode 155, and a first encapsulation film 156. The first light emitting diode 150 can be a vertical type light emitting diode LED in which the first n-type electrode 154 and the first p-type electrode 155 are disposed above and below the first emission layer 152.

First, the first n-type semiconductor layer 151 is disposed on the first connection electrode CE1 and the first p-type semiconductor layer 153 is disposed on the first n-type semiconductor layer 151. The first n-type semiconductor layer 151 and the first p-type semiconductor layer 153 can be semiconductor layers doped with n-type and p-type impurities. For example, the first n-type semiconductor layer 151 and the first p-type semiconductor layer 153 can be layers doped with n-type and p-type impurities into a material such as gallium nitride (GaN), indium aluminum phosphide (InAlP), or gallium arsenide (GaAs). The p-type impurity can be magnesium (Mg), zinc (Zn), beryllium (Be), and the like, and the n-type impurity can be silicon (Si), germanium (Ge), tin (Sn), and the like, but are not limited thereto.

The first emission layer 152 is disposed between the first n-type semiconductor layer 151 and the first p-type semiconductor layer 153. The first emission layer 152 is supplied with holes and electrons from the first n-type semiconductor layer 151 and the first p-type semiconductor layer 153 to emit light. The first emission layer 152 can be formed with a single layer or a multi-quantum well (MQW) structure, and for example, can be formed of indium gallium nitride (InGaN) or gallium nitride (GaN), but is not limited thereto.

The first n-type electrode 154 is disposed between the first n-type semiconductor layer 151 and the first connection electrode CE1. The first n-type electrode 154 is an electrode which electrically connects the first light emitting diode 150 and the power line PL. The first n-type electrode 154 can be in contact with a bottom surface of the first n-type semiconductor layer 151. The first n-type electrode 154 is in contact with the first connection electrode CE1 to be electrically connected to the first connection electrode CE1. The first n-type electrode 154 can be electrically connected to the power line PL through the first connection electrode CE1 and the fifth conductive layer CL5. The first n-type electrode 154 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The first p-type electrode 155 is disposed on the first p-type semiconductor layer 153. The first p-type electrodes 155 is an electrode for electrically connecting the first light emitting diode 150 and the driving transistor DT. The first p-type electrodes 155 can be electrically connected to the source electrode SE or the drain electrode DE of the driving transistor DT through the second connection electrode CE2. The first p-type electrode 155 can be configured by a conductive material, and for example, an opaque conductive material, such as titanium (Ti), gold (Au), silver (Ag), copper (Cu), or an alloy thereof, but is not limited thereto.

A first encapsulation film 156 which encloses the first n-type semiconductor layer 151, the first emission layer 152, the first p-type semiconductor layer 153, the first n-type electrode 154, and the first p-type electrode 155 is disposed. The first encapsulation film 156 is formed of an insulating material to protect the first n-type semiconductor layer 151, the first emission layer 152, and the first p-type semiconductor layer 153. Further, at least a part of the first n-type electrode 154 and the first p-type electrode 155 is exposed from the first encapsulation film 156 to electrically connect the first connection electrode CE1 and the second connection electrode CE2 to the first n-type electrode 154 and the first p-type electrode 155. The first encapsulation film 156 is formed of an insulating material, such as silicon nitride (SiNx) or silicon oxide (SiOx), but is not limited thereto.

A second planarization layer 149 is disposed on the first light emitting diodes 150 and the first planarization layer 148. The second planarization layer 149 is disposed so as to enclose the first light emitting diode 150 to fix and protect the first light emitting diode 150. The second planarization layer 149 can be configured by a single layer or a plurality of layers and can be formed of an organic material. For example, the second planarization layer 149 can be configured by a single layer or a double layer, and for example, can be formed of photoresist or an acrylic-based organic material, but is not limited thereto.

The second connection electrode CE2 is disposed on the second planarization layer 149 in the first sub pixel SP1. The second connection electrodes CE2 is an electrode for electrically connecting the plurality of light emitting diodes LED and the driving transistor DT. The second connection electrodes CE2 can be electrically connected to any one of the source electrode SE or the drain electrode DE of the driving transistor DT, through a contact hole formed in the second planarization layer 149, the first planarization layer 148, the passivation layer 147, and the third interlayer insulating layer 146. Further, the second connection electrodes CE2 can be electrically connected to the first p-type electrode 155 of the first light emitting diode 150 exposed from the second planarization layer 149. The second connection electrode CE2 can be formed of a conductive material, for example, a transparent conductive material, such as indium tin oxide (ITO) or indium zinc oxide (IZO), but is not limited thereto.

A plurality of sixth conductive layers CL6 is disposed on the second planarization layer 149. The plurality of sixth conductive layers CL6 can configure at least a part of the plurality of wiring lines which supplies various signals to the sub pixel SP or a configuration of the pixel circuit. For example, some of the plurality of sixth conductive layers CL6 is electrically connected to the fifth conductive layer CL5 and the other sixth conductive layer can be electrically connected to the fourth conductive layer CL4. The plurality of sixth conductive layers CL6 is formed of a conductive material, for example, a transparent conductive material, such as indium tin oxide (ITO) or indium zinc oxide (IZO), but is not limited thereto.

A first reflective layer RL1 is disposed on a side portion of the first light emitting diode 150 in the first sub pixel SP1. The first light emitting diode 150 can be disposed in an area between the first reflective layer RL1 and the light conversion layer CCL. A V-shaped first groove 149a is disposed in a position of the second planarization layer 145 adjacent to the first light emitting diode 150 and the first reflective layer RL1 can be disposed on a surface in the V-shaped first groove 149a. The first reflective layer RL1 is a reflective layer which reflects light emitted from the first light emitting diode 150 to the light conversion layer CCL. The first light emitting diode 150 has one side surface facing the light conversion layer CCL and an opposite surface of one side surface. The first reflective layer RL1 can be disposed so as to be face the opposite surface of one side surface of the first light emitting diode 150. One side surface of the first light emitting diode 150 can face the light conversion layer CCL and the opposite surface of one side surface of the first light emitting diode 150 can face the first reflective layer RL1. The first reflective layer RL1 can be formed of a material having a high reflection efficiency, and for example, an opaque conductive material, such as titanium (Ti), gold (Au), silver (Ag), copper (Cu), or an alloy thereof, but is not limited thereto.

At this time, the first groove 149a and the first reflective layer RL1 can be disposed to be spaced apart from the first light emitting diode 150. If the first groove 149a is disposed so as to overlap the first light emitting diode 150 to expose the first light emitting diode 150 in the first groove 149a and cover the entire side surface of the first light emitting diode 150 by the first reflective layer RL1, the short defect that allows the first reflective layer RL1 to electrically connect the first n-type electrode 154 and the first p-type electrode 155 can be caused. Therefore, the first groove 149a and the first reflective layer RL1 can be disposed to be separated from the first light emitting diode 150.

In the meantime, even though in the drawing, it is illustrated that a planar shape of the first reflective layer RL1 has a straight line shape, the planar shape of the first reflective layer RL1 is not limited thereto. For example, the planar shape of the first reflective layer RL1 can enclose at least a part of remaining side surfaces of the first light emitting diodes 150, excluding one side surface of the first light emitting diodes 150 facing the light conversion layer CCL.

As the first p-type electrode 155 is formed of an opaque conductive material, most of light emitted from the first light emitting diode 150 can be emitted to the lateral direction of the first light emitting diode 150, rather than the upward direction. At this time, the first reflective layer RL1 disposed on a side portion of the first light emitting diode 150 reflects light which travels to be far from the light conversion layer CCL, among light emitted from the first light emitting diode 150, to the light conversion layer CCL again to improve the light conversion efficiency of the light conversion layer CCL.

Further, the first connection electrode CE1 is formed of an opaque conductive material to improve the light conversion efficiency of the light conversion layer CCL. For example, the first connection electrode CE1 formed of the opaque conductive material can reflect light which is directed to the lower portion of the first light emitting diode 150, among light emitted from the first light emitting diode 150. Further, the light reflected from the first connection electrode CE1 can be reflected to the light conversion layer CCL by the first p-type electrode 155 and the first reflective layer RL1.

At this time, the second connection electrode CE2 can be disposed on the first reflective layer RL1. At least a part of the second connection electrode CE2 can be disposed in the first groove 149a of the second planarization layer 149 in which the first reflective layer RL1 is located. Specifically, after forming the second planarization layer 149 which covers the first light emitting diode 150 and forming the first groove 149a in the second planarization layer 149, the first reflective layer RL1 can be formed in the first groove 149a. Next, the second connection electrode CE2 can be formed on the second planarization layer 149 and the first reflective layer RL1. Accordingly, the process is performed in the order of the first reflective layer RL1 and the second connection electrode CE2 so that the first reflective layer RL1 and the second connection electrode CE2 can be in contact with each other in the first groove 149a.

In the meantime, a part of the second planarization layer 149 is disposed between the first reflective layer RL1 and the first light emitting diode 150 so that the first reflective layer RL1 can be disposed to be spaced apart from the first light emitting diode 150 and the first connection electrode CE1. Therefore, a short defect which is caused when the first reflective layer RL1 which is in contact with the second connection electrode CE2 is connected to the first connection electrode CE1 or the first n-type electrode 154 can be suppressed.

A second groove 149b is formed in the second planarization layer 149 and the light conversion layer CCL is disposed in the second groove 149b. Referring to FIGS. 2 and 3, the second groove 149b of the second planarization layer 149 can be disposed on a side portion of the first light emitting diode 150 in the first sub pixel SP1. The second groove 149b can extend to be long toward one direction. The second groove 149b and the first groove 149a can be disposed on one straight line and the first light emitting diode 150 can be disposed between the second groove 149b and the first groove 149a. The first light emitting diode 150 and the first reflective layer RL1 can be disposed along a length direction of the light conversion layer CCL.

The light conversion layer CCL disposed in the second groove 149b can convert light emitted from the first light emitting diode 150 into red light. The light conversion layer CCL can include a color conversion material, such as a quantum dot, a nano fluorescent material or an organic fluorescent material. The color conversion material included in the light conversion layer CCL absorbs light emitted from the first light emitting diode 150 to emit light having a different wavelength. Light which is incident from the first light emitting diode 150 and the first reflective layer RL1 onto the light conversion layer CCL is converted into red light by the light conversion layer CCL to be emitted to the outside of the display device 100.

A second reflective layer RL2 is disposed between the second groove 149b and the light conversion layer CCL. The second reflective layer RL2 can reflect red light which is converted by the light conversion layer CCL to the upper portion of the light conversion layer CCL. The second reflective layer RL2 can be disposed on an inner surface, other than an inner surface of the second groove 149b which faces to the first light emitting diode 150, among a plurality of inner surfaces of the second groove 149b. For example, the second reflective layer RL2 can be disposed on three inner surfaces, other than one inner surface which is opposite to the first light emitting diode 150, among four inner surfaces of the second groove 149b and a bottom surface of the second groove 149b. Therefore, light from the first light emitting diode 150 can travel to the light conversion layer CCL through one surface of the second groove 149b in which the second reflective layer RL2 is not disposed. For example, the second reflective layer RL2 can be formed of an opaque conductive material having a high reflection efficiency, such as titanium (Ti), gold (Au), silver (Ag), copper (Cu), or an alloy thereof, but is not limited thereto.

Next, referring to FIGS. 2, 4, and 5, a plurality of connection lines 130 is disposed on the plurality of line patterns. The plurality of connection lines 130 refers to wiring lines which electrically connect the pads on the plurality of first plate patterns 121 and the plurality of second plate patterns 123. The plurality of connection lines 130 is disposed on the plurality of first line patterns 122 and the plurality of second line patterns 124. The plurality of connection lines 130 can extend onto the plurality of first plate patterns 121 to be electrically connected to the plurality of pads on the plurality of first plate patterns 121. The plurality of first line patterns 122 is not disposed in an area where the plurality of connection lines 130 is not disposed, among areas between the plurality of first plate patterns 121. Further, the plurality of connection lines 130 is disposed on the plurality of second line patterns 124 to be electrically connected to a pad on the plurality of second plate patterns 123 and a pad on the plurality of first plate patterns 121.

The plurality of connection lines 130 includes a first connection line 131 and a second connection line 132. The first connection line 131 and the second connection line 132 are disposed between the plurality of first plate patterns 121, between the plurality of second plate patterns 123, and between the plurality of first plate patterns 121 and the plurality of second plate patterns 123. Specifically, the first connection line 131 refers to a wiring line extending in the first direction D1 between the plurality of first plate patterns 121, between the plurality of second plate patterns 123, and between the plurality of first plate patterns 121 and the plurality of second plate patterns 123, among the connection lines 130. The second connection line 132 refers to a wiring line extending in the second direction D2 between the plurality of first plate patterns 121, between the plurality of second plate patterns 123, and between the plurality of first plate patterns 121 and the plurality of second plate patterns 123. Here, the first direction D1 and the second direction D2 can also be referred to as a row direction and a column direction, respectively.

The plurality of connection lines 130 can be formed of a conductive material. For example, the plurality of connection lines 130 can be formed of a metal material such as copper (Cu), aluminum (Al), titanium (Ti), and molybdenum or a stacked structure of metal materials such as copper/molybdenum-titanium (Cu/Moti) or titanium/aluminum/titanium (Ti/Al/Ti), but is not limited thereto.

In the case of a general display device, various wiring lines such as a plurality of scan lines and a plurality of data lines extend between the plurality of sub pixels with a straight line shape and the plurality of sub pixels is connected to one signal line. Therefore, in the general display device, various wiring lines, such as a scan line, a data line, a high potential voltage line, and a reference voltage line, extend from one side to the other side of the display device without being disconnected on the substrate.

In contrast, in the display device 100 according to the example embodiment of the present disclosure, various wiring lines, such as a scan line, a data line, a high potential voltage line, a reference voltage line, and an initialization voltage line having a straight line shape which are considered to be used for the general display device, are disposed only on the plurality of first plate patterns 121 and the plurality of second plate patterns 123. For example, in the display device 100 according to the example embodiment of the present disclosure, a straight line-shaped wiring line is disposed only on the plurality of first plate patterns 121 and the plurality of second plate patterns 123.

In the display device 100 according to the example embodiment of the present disclosure, the pads on two adjacent first plate patterns 121 can be connected by the connection lines 130. Accordingly, the connection line 130 electrically connects the pads on two adjacent first plate patterns 121. Accordingly, the display device 100 according to the example embodiment of the present disclosure can include a plurality of connection lines 130 so as to electrically connect various wiring lines, such as a scan line, a data line, a high potential voltage line, and a reference voltage line, between the plurality of first plate patterns 121. For example, the scan line can be disposed on the plurality of first plate patterns 121 disposed to be adjacent to each other in the first direction D1 and the pads can be disposed on both ends of the scan line. At this time, the plurality of pads on the plurality of first plate patterns 121 adjacent to each other in the first direction D1 can be connected to each other by the first connection line 131 which serves as a scan line. Therefore, the scan line disposed on the plurality of first plate patterns 121 and the first connection line 131 disposed on the first line pattern 122 can serve as one scan line. Further, wiring lines which extend in the first direction D1, among all various wiring lines which can be included in the display device 100, such as an emission signal line, a low potential voltage line, and a high potential voltage line, can also be electrically connected by the first connection line 131, as described above.

A plurality of first connection lines 131 of the active area AA can connect the pads on two first plate patterns 121 which are disposed side by side, among the pads on the plurality of first plate patterns 121 disposed to be adjacent in the first direction D1. For example, the pads on the plurality of first plate patterns 121 disposed in the first direction D1 can be connected by the first connection line 131 serving as a scan line and transmit a scan signal to each of the plurality of sub pixels SP. However, the plurality of first connection lines 131 can connect an emission signal line, a high potential voltage line, or a low potential voltage line, in addition to the scan line, but is not limited thereto.

A plurality of second connection lines 132 can connect the pads on two first plate patterns 121 which are disposed side by side, among the plurality of first plate patterns 121 disposed to be adjacent in the second direction D2. An internal line on the plurality of first plate patterns 121 disposed in the second direction D2 can be connected by the plurality of second connection lines 132 serving as a data line and transmit a data voltage to each of the plurality of sub pixels SP. However, the plurality of second connection lines 132 can connect data lines, high potential voltage lines, low potential voltage lines, or reference lines, but is not limited thereto.

Further, referring to FIGS. 4 and 5, end portions of the plurality of connection lines 130 can be connected to the pads on the first plate patterns 121. For example, the fifth conductive layer CL5 which serves as a pad is disposed on the third interlayer insulating layer 146 of the first plate pattern 121. Any one of the plurality of connection lines 130 extends from the first line pattern 122 to side surfaces and a top surface of the first planarization layer 148 and can be electrically connected to the fifth conductive layer CL5 through a contact hole. Further, another one of the plurality of connection lines 130 extends to a side surface and a top surface of the second planarization layer 149 to be electrically connected to a pad on the first plate pattern 121.

Next, referring to FIGS. 2 and 4, in the second sub pixel SP2, the second light emitting diode 160 is disposed on the first planarization layer 148. A second light emitting diode 160 which is a green light emitting diode is disposed in the second sub pixel SP2 which is a green sub pixel SP. The second light emitting diode 160 can be a flip-chip type light emitting diode LED in which a second n-type electrode 164 and a second p-type electrode 165 are disposed in a horizontal direction below a second emission layer 162. Therefore, as compared with the first sub pixel SP1, a placement structure of the second connection electrode CE2 for connecting the second light emitting diode 160 and the driving transistor DT can be different in the second sub pixel SP2.

First, the first connection electrode CE1 and the second connection electrode CE2 can be disposed on the first planarization layer 148. The first connection electrode CE1 can be connected to the fifth conductive layer CL5 through a contact hole formed in the first planarization layer 148 and the passivation layer 147. Therefore, the first connection electrode CE1 can be electrically connected to the power line PL through the fifth conductive layer CL5. Further, the second connection electrodes CE2 can be electrically connected to any one of the source electrode SE or the drain electrode DE of the driving transistor DT, through a contact hole formed in the first planarization layer 148, the passivation layer 147, and the third interlayer insulating layer 146.

Further, the second light emitting diode 160 is disposed on the first connection electrode CE1 and the second connection electrode CE2. The second light emitting diode 160 includes a second n-type semiconductor layer 161, a second emission layer 162, a second p-type semiconductor layer 163, a second n-type electrode 164, a second p-type electrode 165, and a second encapsulation film 166.

Specifically, the second p-type semiconductor layer 163 is disposed on the first connection electrode CE1 and the second connection electrode CE2 and the second n-type semiconductor layer 161 is disposed on the second p-type semiconductor layer 163. The second n-type semiconductor layer 161 and the second p-type semiconductor layer 163 can be semiconductor layers doped with n-type and p-type impurities. For example, the second n-type semiconductor layer 161 and the second p-type semiconductor layer 163 can be layers doped with n-type and p-type impurities into a material such as gallium nitride (GaN), indium aluminum phosphide (InAlP), or gallium arsenide (GaAs). The p-type impurity can be magnesium (Mg), zinc (Zn), and beryllium (Be), and the n-type impurity can be silicon (Si), germanium (Ge), and tin (Sn), but are not limited thereto.

The second emission layer 162 is disposed between the second n-type semiconductor layer 161 and the second p-type semiconductor layer 163. The second emission layer 162 is supplied with holes and electrons from the second n-type semiconductor layer 161 and the second p-type semiconductor layer 163 to emit light. The second emission layer 162 can be formed by a single layer or a multi-quantum well (MQW) structure, and for example, can be formed of indium gallium nitride (InGaN) or gallium nitride (GaN), but is not limited thereto.

The second n-type electrode 164 is disposed between the second n-type semiconductor layer 161 and the first connection electrode CE1. The second n-type electrode 164 is an electrode which electrically connects the second light emitting diode 160 and the power line PL. The second n-type electrode 164 can be in contact with a bottom surface of the second n-type semiconductor layer 162 which protrudes from the second emission layer 162 and the second p-type semiconductor layer 163. Further, the second n-type electrode 164 is in contact with the first connection electrode CE1 to be electrically connected to the first connection electrode CE1. Therefore, the second n-type electrode 164 can be electrically connected to the power line PL through the first connection electrode CE1 and the fifth conductive layer CL5. The second n-type electrode 164 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second p-type electrode 165 is disposed between the second p-type semiconductor layer 163 and the second connection electrode CE2. The second p-type electrodes 165 is an electrode for electrically connecting the second light emitting diode 160 and the driving transistor DT. The second p-type electrode 165 can be electrically connected to any one of the source electrode SE or the drain electrode DE of the driving transistor DT through the second connection electrode CE2. The second p-type electrode 165 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

A second encapsulation film 166 which encloses the second n-type semiconductor layer 161, the second emission layer 162, the second p-type semiconductor layer 163, the second n-type electrode 164, and the second p-type electrode 165 is disposed. The second encapsulation film 166 is formed of an insulating material to protect the second n-type semiconductor layer 161, the second light emitting layer 162, and the second p-type semiconductor layer 163. Further, at least a part of the second n-type electrode 164 and the second p-type electrode 165 is exposed from the second encapsulation film 166 to electrically connect the first connection electrode CE1 and the second connection electrode CE2 to the second n-type electrode 164 and the second p-type electrode 165. The second encapsulation film 166 can be formed of an insulating material, such as silicon nitride (SiNx) or silicon oxide (SiOx), but is not limited thereto.

In the meantime, the second light emitting diode 160 disposed in the second sub pixel SP2 which is a green sub pixel SP is a green light emitting diode so that a separate light conversion layer CCL for converting green light from the second light emitting diode 160 is not disposed in the second sub pixel SP2. For example, in the second sub pixel SP2, green light from the second light emitting diode 160 can emit to the outside of the display device 100 as it is.

A conductive adhesive layer AD is disposed between the second light emitting diode 160 and the first connection electrode CE1 and between the second light emitting diode 160 and the second connection electrode CE2. The conductive adhesive layer AD can be disposed between the second n-type electrode 164 and the second p-type electrode 165 of the second light emitting diode 160 and the first connection electrode CE1 and the second connection electrode CE2. The conductive adhesive layer AD can be an adhesive layer in which conductive balls are dispersed in an insulating base member. When heat or pressure is applied to the conductive adhesive layer AD, the conductive balls are electrically connected in a portion applied with heat or pressure to have a conductive property and an area which is not pressurized can have an insulating property. Accordingly, the second light emitting diode 160 is disposed on the conductive adhesive layer AD and heat or pressure is applied thereto to electrically connect the second n-type electrode 164 and the second p-type electrode 165 of the second light emitting diode 160 and the first connection electrode CE1 and the second connection electrode CE2. At this time, it is illustrated that the conductive adhesive layers AD which cover the first connection electrode CE1 and the second connection electrode CE2 are connected. However, the conductive adhesive layers AD can be separated to be disposed above the first connection electrode CE1 and the second connection electrode CE2, respectively.

Next, referring to FIG. 5, the third sub pixel SP3 can be a blue sub pixel SP which emits blue light. Further, a structure of the third sub pixel SP3 can be substantially the same as the structure of the second sub pixel SP2. Specifically, the first connection electrode CE1 and the second connection electrode CE2 can be disposed on the first planarization layer 148 also in the third sub pixel SP3.

Further, in the third sub pixel SP3, the third light emitting diode 170 which emits blue light can be disposed. The third light emitting diode 170 can be substantially the same as the second light emitting diode 160, except that blue light is emitted. Therefore, a separate light conversion layer CCL may not be disposed in the third sub pixel SP3.

Specifically, the third light emitting diode 170 includes a third n-type semiconductor layer 171, a third emission layer 172, a third p-type semiconductor layer 173, a third n-type electrode 174, a third p-type electrode 175, and a third encapsulation film 176. The third light emitting diode 170 can be a flip-chip type light emitting diode LED in which a third n-type electrode 174 and a third p-type electrode 175 are disposed in a horizontal direction below a third emission layer 172.

The third n-type semiconductor layer 171, the third p-type semiconductor layer 173, the third n-type electrode 174, the third p-type electrode 175, and the third encapsulation film 176 of the third light emitting diode 170 can be substantially the same as the second n-type semiconductor layer 161, the second p-type semiconductor layer 163, the second n-type electrode 164, the second p-type electrode 165, and the second encapsulation film 166. Further, the third emission layer 172 of the third light emitting diode 170 emits blue light and the second emission layer 162 of the second light emitting diode 160 can emit green light.

In the meantime, in the present disclosure, it is described that the second light emitting diode 160 of the second sub pixel SP2 and the third light emitting diode 170 of the third sub pixel SP3 are flip-chip types. However, the second light emitting diode 160 and the third light emitting diode 170 can have the vertical structure which is the same as the first light emitting diode 150 or can have a lateral structure, but are not limited thereto.

Further, in the present disclosure, it is described that the second light emitting diode 160 and the third light emitting diode 170 which emit green light and blue light are disposed in the second sub pixel SP2 and the third sub pixel SP3, respectively so that a green light conversion layer and a blue light conversion layer are not disposed in the second sub pixel SP2 and the third sub pixel SP3. However, a green light conversion layer and a blue light conversion layer can be further disposed in the second sub pixel SP2 and the third sub pixel SP3, respectively, but are not limited thereto.

In the third sub pixel SP3 which is a blue sub pixel SP, a third light emitting diode 170 which emits blue light is disposed so that there is no need to dispose a separate light conversion layer CCL. Further, in the second sub pixel SP2 which is a green sub pixel SP, a second light emitting diode 160 which emits green light is disposed so that there is no need to dispose a separate light conversion layer CCL. Therefore, the second light emitting diode 160 and the third light emitting diode 170 which emit green light and blue light are disposed in the second sub pixel SP2 and the third sub pixel SP3 so that green and blue images can be displayed.

In the meantime, the first light emitting diode 150 disposed in the first sub pixel SP1 which is a red sub pixel SP emits green light or blue light so that a light conversion layer CCL for converting green light or blue light from the first light emitting diode 150 can be further disposed in the first sub pixel SP1. Specifically, the red light emitting diode which emits red light can have an efficiency inferior to the green light emitting diode and the blue light emitting diode. Therefore, in the first sub pixel SP1, the light conversion layer CCL is further formed in the green light emitting diode or the blue light emitting diode which has a better efficiency, instead of the red light emitting diode, to implement red light.

Further, in the related art, a light conversion efficiency of the light conversion layer is increased by disposing the light conversion layer above the light emitting diode and forming the light conversion layer to have a larger thickness. However, there are problem in that a process time or a manufacturing cost required to form the light conversion layer to have a large thickness is limited and it is difficult to increase the light conversion efficiency to a predetermined level or higher.

Accordingly, in the display device 100 according to the example embodiment of the present disclosure, a light conversion layer CCL having a length which is long in a horizontal direction is formed on a side portion of the first light emitting diode 150 to increase a light conversion efficiency of the light conversion layer CCL. The light conversion layer CCL has a length long in the horizontal direction so that a probability of absorbing and converting light which moves toward the light conversion layer CCL in the horizontal direction in a light conversion material. Finally, a light conversion efficiency is improved. Further, the first p-type electrode 155 of the first light emitting diode 150 is formed of an opaque conductive material. The first reflective layer RL1 which reflects light from the first light emitting diode 150 to the light conversion layer CCL is formed on a side portion of the first light emitting diode 150 to transmit more light to the light conversion layer CCL. Accordingly, the light conversion layer CCL which has a length long in the horizontal direction is formed on a side portion of the first light emitting diode 150. The light from the first light emitting diode 150 is reflected to the light conversion layer CCL to improve the light conversion efficiency of the light conversion layer CCL.

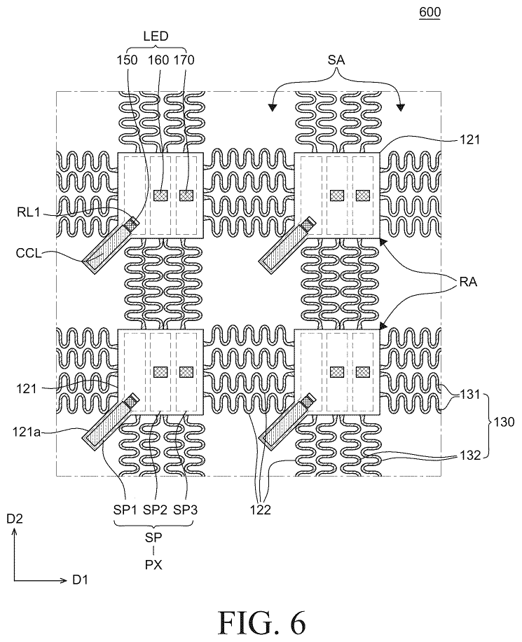

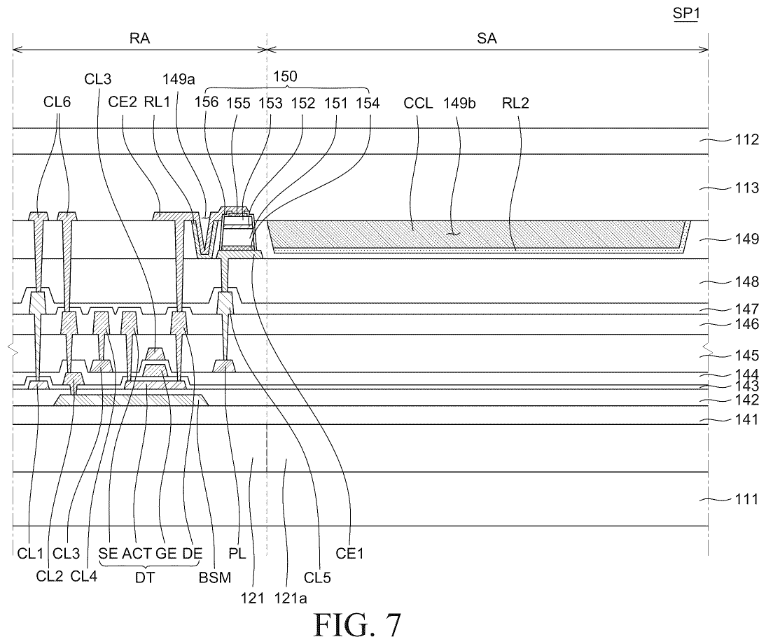

FIG. 6 is an enlarged plan view of an active area of a display device according to another example embodiment of the present disclosure. FIG. 7 is a cross-sectional view of a first sub pixel of a display device according to another example embodiment of the present disclosure. The only difference between a display device 600 of FIGS. 6 and 7 and the display device 100 of FIGS. 1 to 5 is a first plate pattern 121 and a first sub pixel SP1, but other configurations are the same or substantially the same, so that a redundant description will be omitted or may be briefly provided.

Referring to FIGS. 6 and 7, each of a plurality of first plate patterns 121 of a display device 600 according to another example embodiment of the present disclosure has a protrusion 121a which extends in an inclined direction from the first plate pattern 121. For example, a planar shape of the first plate pattern 121 can be a rectangular shape and the protrusion 121a can be a part which protrudes from any one of four corners of the first plate pattern 121 toward a malleable area SA.

The plurality of first plate patterns 121 is disposed to form a plurality of rows and a plurality of columns along the first direction D1 and the second direction D2. A plurality of connection lines 130 extending in the first direction D1 and the second direction D2 can be disposed between the plurality of first plate patterns 121. At this time, a malleable area SA in a diagonal direction of the plurality of first plate patterns 121, for example, a malleable area SA in an inclined direction to the first direction D1 and the second direction D2 can be an empty space in which the connection line 130 or the first plate pattern 121 is not disposed. Further, in the empty space in which the first plate pattern 121 and the connection line 130 are not disposed, the protrusion 121a of the first plate pattern 121 can be disposed.

The protrusion 121a can be an area in which the light conversion layer CCL is disposed. The protrusion 121a in which the light conversion layer CCL is disposed can be an area included in the first sub pixel SP1. The first sub pixel SP1 can include an area on the first plate pattern 121 and an area on the protrusion 121a. The first sub pixel SP1 can be disposed in both a rigid area RA corresponding to the first plate pattern 121 and a malleable area SA corresponding to the protrusion 121a. In contrast, the second sub pixel SP2 and the third sub pixel SP3 can be disposed in the rigid area RA corresponding to the first plate pattern 121.

A multi-buffer layer 141, an active buffer layer 142, a gate insulating layer 143, a first interlayer insulating layer 144, a second interlayer insulating layer 145, a third interlayer insulating layer 146, a passivation layer 147, a first planarization layer 148, and a second planarization layer 149 can be disposed on the protrusion 121a of the first plate pattern 121. A plurality of insulating layers disposed on the first plate pattern 121 can be disposed to extend to the protrusion 121a. Accordingly, the plurality of insulating layers which is the same as those disposed on the first plate pattern 121 is disposed on the protrusion 121a to minimize a step of the first light emitting diode 150 disposed on the first plate pattern 121 and the light conversion layer CCL disposed on the protrusion 121a.

A second groove 149b can be disposed in the second planarization layer 149 on the protrusion 121a. The second groove 149b of the second planarization layer 149 can be disposed so as to correspond to the protrusion 121a. Further, the light conversion layer CCL is disposed in the second groove 149b of the second planarization layer 149. The light conversion layer CCL is disposed on the protrusion 121a to convert light from the first light emitting diode 150 into red light.

At this time, the light conversion layer CCL can extend in an inclined direction to the first direction D1 and the second direction D2, like the protrusion 121a. The first light emitting diode 150 is aligned to face the light conversion layer CCL. The first reflective layer RL1 can be also disposed to be aligned to be inclined toward the light conversion layer CCL. The first reflective layer RL1, the first light emitting diode 150, and the light conversion layer CCL can be disposed along an inclined direction in one line.

Accordingly, in the display device 600 according to another example embodiment of the present disclosure, the light conversion layer CCL can be disposed in the malleable area SA in which the plurality of first plate patterns 121 and the plurality of connection lines 130 are not disposed. The plurality of first plate patterns 121 is disposed to form the plurality of rows and the plurality of columns. The plurality of connection lines 130 disposed along the first direction D1 and the second direction D2 can be disposed between the plurality of first plate patterns 121. Therefore, a diagonal area of the plurality of first plate patterns 121 is an empty area in which the first plate pattern 121 or the connection line 130 is not disposed and can be a malleable area SA. The protrusion 121a extending from the first plate pattern 121 is disposed in the malleable area SA and the plurality of insulating layers and the light conversion layer CCL are disposed on the protrusion 121a to convert light from the first light emitting diode 150 into red light. The empty space is utilized as an area in which the protrusion 121a and the light conversion layer CCL are disposed to easily form the light conversion layer CCL in the display device 600 without being limited to a size on the first plate pattern 121. Accordingly, in the display device 600 according to another example embodiment of the present disclosure, the light conversion layer CCL is formed in the malleable area SA in the diagonal direction of the plurality of first plate patterns 121 to easily convert light from the first light emitting diode 150.

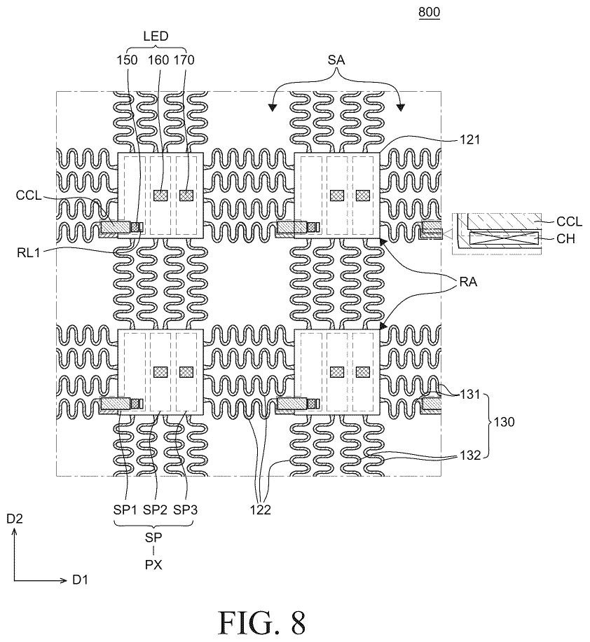

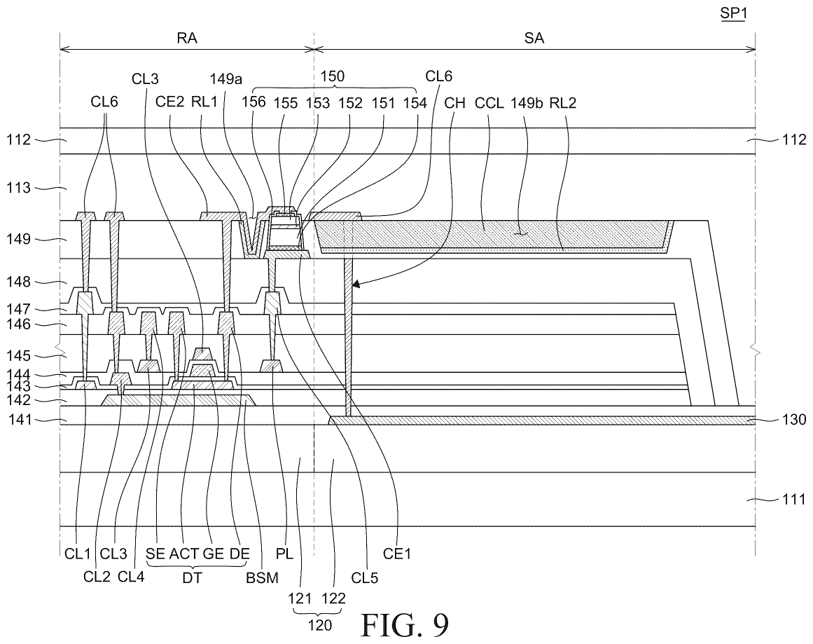

FIG. 8 is an enlarged plan view of an active area of a display device according to still another example embodiment of the present disclosure. FIG. 9 is a cross-sectional view of a first sub pixel of a display device according to still another example embodiment of the present disclosure. The only difference between a display device 800 of FIGS. 8 and 9 and the display device 100 of FIGS. 1 to 5 is a first sub pixel SP1, but other configurations are the same or substantially the same, so that a redundant description will be omitted or may be briefly provided.

Referring to FIGS. 8 and 9, the light conversion layer CCL is disposed on some first line pattern 122 among the plurality of first line patterns 122. For example, the light conversion layer CCL of the first sub pixel SP1 can be disposed in one of the plurality of first line patterns 122 extending in the first direction D1. The light conversion layer CCL can be disposed on a partial area of the first line pattern 122 adjacent to the first plate pattern 121, among the first line patterns 122. The light conversion layer CCL can be disposed on the malleable area SA corresponding to the first line pattern 122. As the light conversion layer CCL is disposed on the first line pattern 122, the first sub pixel SP1 can include an area on the first plate pattern 121 and an area on the first line pattern 122. The first sub pixel SP1 can be disposed in both a rigid area RA corresponding to the first plate pattern 121 and a malleable area SA corresponding to the first line pattern 122. Further, the first line pattern 122 in which the light conversion layer CCL is disposed can include a part in which the light conversion layer CCL is disposed and a part in which the connection line 130 is disposed.

Further, in order to minimize a step between the light conversion layer CCL disposed on the first line pattern 122 and the first light emitting diode 150 disposed on the first planarization layer 148 of the first plate pattern 121, a plurality of insulating layers can also be disposed on the first line pattern 122. For example, a multi-buffer layer 141, an active buffer layer 142, a gate insulating layer 143, a first interlayer insulating layer 144, a second interlayer insulating layer 145, a third interlayer insulating layer 146, a passivation layer 147, a first planarization layer 148, and a second planarization layer 149 can be disposed between the first line pattern 122 and the light conversion layer CCL. Accordingly, the light conversion layer CCL disposed on the first line pattern 122 and the first light emitting diode 150 disposed on the first plate pattern 121 are disposed at the substantially same height to face each other. The light from the first light emitting diode 150 can be easily transmitted to the light conversion layer CCL.

A second groove 149b is disposed in the second planarization layer 149 disposed on the first line pattern 122 and the light conversion layer CCL can be disposed in the second groove 149b. In the area which overlaps the first line pattern 122, the second groove 149b is formed in the second planarization layer 149 to dispose the light conversion layer CCL in the area on the first line pattern 122.

In the meantime, the plurality of lines on the first plate pattern 121 is electrically connected to the connection line 130 on the first line pattern 122 to be applied with a signal. In this case, an end portion of each of the plurality of connection lines 130 extends onto the first plate pattern 121 to be connected to a pad on the first plate pattern 121 or be directly connected to the plurality of lines on the first plate pattern 121.

Therefore, as the light conversion layer CCL is disposed on a part of the first line pattern 122 adjacent to the first plate pattern 121, the plurality of wiring lines on the first plate pattern 121 and the connection line 130 on the first line pattern 122 can be connected to each other through a separate contact hole CH. For example, referring to FIG. 8, any one of the plurality of sixth conductive layers CL6 disposed on the first plate pattern 121 can be electrically connected to the connection line 130 through a contact hole CH formed in a partial area of the first line pattern 122 corresponding to the first sub pixel SP1. An end portion of the connection line 130 is disposed in a partial area of the first line pattern 122 corresponding to the first sub pixel SP1. The sixth conductive layer CL6 can be electrically connected to an end portion of the connection line 130 through a contact hole CH formed in the second planarization layer 149, the first planarization layer 148, the passivation layer 147, the third interlayer insulating layer 146, the second interlayer insulating layer 145, the first interlayer insulating layer 144, the gate insulating layer 143, the active buffer layer 142, and the multi-buffer layer 141. However, a connection structure of the connection line 130 is illustrative, but is not limited thereto.

Next, the first light emitting diode 150 can be disposed to be adjacent to the light conversion layer CCL. The first light emitting diode 150 can be disposed to be adjacent to the first line pattern 122. The first light emitting diode 150 on the first plate pattern 121 and the light conversion layer CCL on the first line pattern 122 can be disposed to face each other.

Further, the first reflective layer RL1 can be disposed to face an opposite surface of one side surface of the first light emitting diode 150 which faces the light conversion layer CCL. One side surface of the first light emitting diode 150 can face the light conversion layer CCL and the opposite surface of one side surface of the first light emitting diode 150 can face the first reflective layer RL1. The first reflective layer RL1, the first light emitting diode 150, and the light conversion layer CCL can be disposed along a length direction of the light conversion layer CCL in one line. Accordingly, light which travels to be far from the light conversion layer CCL, among light from the first light emitting diode 150 can be reflected to the light conversion layer CCL, by the first reflective layer RL1. Further, light which upwardly travels, among light emitted from the first emission layer 152 of the first light emitting diode 150 can be reflected to the light conversion layer CCL by the first p-type electrode 155 and the first reflective layer RL1.

Accordingly, in the display device 800 according to still another example embodiment of the present disclosure, the light conversion layer CCL can be disposed on the first line pattern 122. The light conversion layer CCL can be disposed on a partial area of the first line pattern 122 adjacent to the first plate pattern 121. The light conversion layer CCL is disposed on a partial area on the first line pattern 122 without being limited to an area on the first plate pattern 121. Further, a plurality of insulating layers is disposed on the first line pattern 122 to minimize the step of the light conversion layer CCL on the first line pattern 122 and the first light emitting diode 150 on the first plate pattern 121 to easily transmit light from the first light emitting diode 150 to the light conversion layer CCL. Accordingly, the light conversion layer CCL is formed by utilizing an area on the first line pattern 122 to easily convert light from the first light emitting diode 150 into red light.

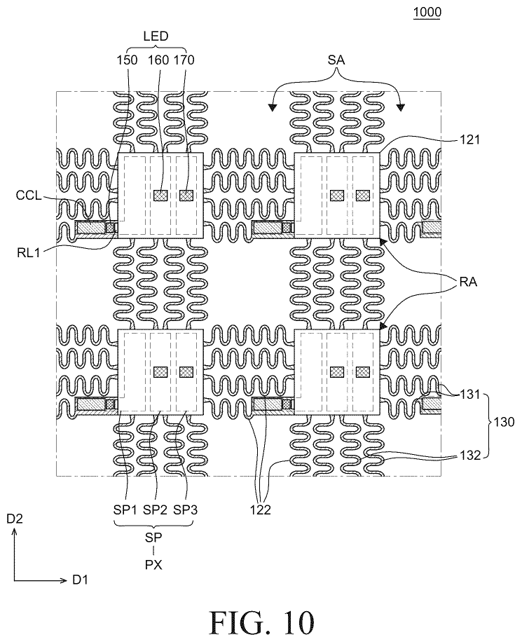

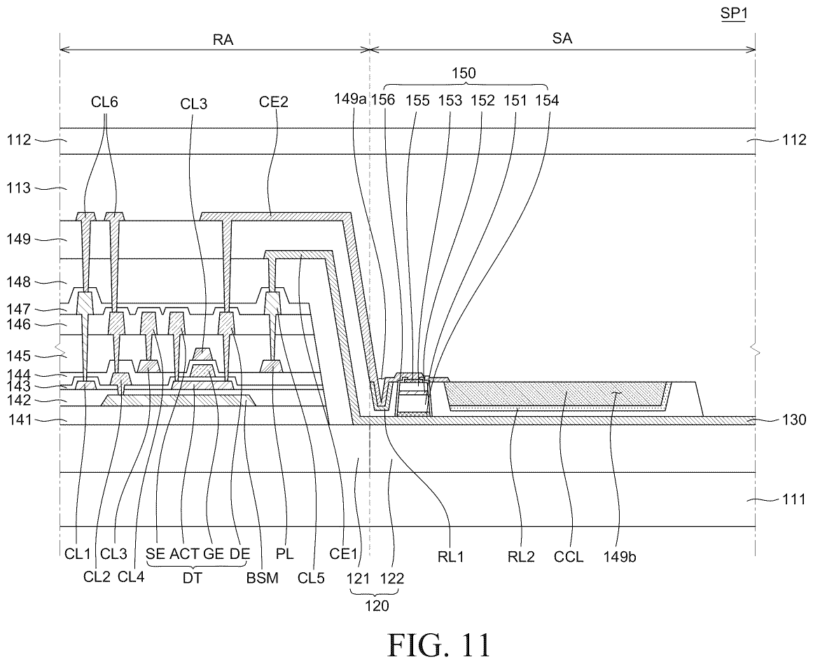

FIG. 10 is an enlarged plan view of an active area of a display device according to still another example embodiment of the present disclosure. FIG. 11 is a cross-sectional view of a first sub pixel of a display device according to still another example embodiment of the present disclosure. The only difference between a display device 1000 of FIGS. 10 and 11 and the display device 100 of FIGS. 1 to 5 is a first sub pixel SP1, but other configurations are the same or substantially the same, so that a redundant description will be omitted or may be briefly provided.

Referring to FIGS. 10 and 11, the first light emitting diode 150 of the first sub pixel SP1 and the light conversion layer CCL are disposed on the first line pattern 122. The first light emitting diode 150 of the first sub pixel SP1 and the light conversion layer CCL are disposed in the malleable area SA corresponding to the first line pattern 122 and the pixel circuit of the first sub pixel SP1 is disposed in the rigid area RA corresponding to the first plate pattern 121.

First, the connection line 130 connected to the first connection electrode CE1 can be disposed on the first line pattern 122. The connection line 130 extends from the first line pattern 122 onto the first planarization layer 148 of the first plate pattern 121 to be electrically connected to the first connection electrode CE1 on the first planarization layer 148. The connection line 130 can be in contact with a top surface of the first line pattern 122, a side surface of the first planarization layer 148, and a top surface of the first planarization layer 148. Further, the connection line 130 can be connected to the first connection electrode CE1 disposed on the top surface of the first planarization layer 148.

The first light emitting diode 150 is disposed on the first line pattern 122 and the connection line 130 in the malleable area SA. The first n-type electrode 154 is in contact with the top surface of the connection line 130 so that the first light emitting diode 150 can be electrically connected to the connection line 130 and the first connection electrode CE1.

Next, the second planarization layer 149 is disposed on the first planarization layer 148, the first connection electrode CE1, the connection line 130, and the first light emitting diode 150. The second planarization layer 149 can be disposed in at least a part of a rigid area RA in which the first plate pattern 121 is disposed and a malleable area SA in which the first line pattern 122 is disposed. The second planarization layer 149 can cover an end portion of the connection line 130 disposed on the first planarization layer 148. Further, the second planarization layer 149 can be disposed in a partial area on the first line pattern 122 in which the first light emitting diode 150 and the light conversion layer CCL are located. The second planarization layer 149 can be disposed so as to cover a part of the first light emitting diode 150 and the connection line 130 in the area on the first line pattern 122.

The first reflective layer RL1 is disposed in the first groove 149a of the second planarization layer 149. The first groove 149a and the first reflective layer RL1 can overlap a partial area of the first line pattern 122 adjacent to the first plate pattern 121 and the connection line 130. At this time, the connection line 130 may not be exposed from the first groove 149a so as not to cause a short defect caused when the first reflective layer RL1 is connected to both the first connection electrode CE1 and the connection line 130 and the second connection electrode CE2. A depth of the first groove 149a is formed to be shallower than a thickness of the second planarization layer 149. Therefore, the first groove 149a of the second planarization layer 149 is disposed so as to overlap the connection line 130, but the first groove 149a is formed to be shallower than the thickness of the second planarization layer 149 so that the connection line 130 may not be exposed from the first groove 149a. Accordingly, in the first groove 149a, the first reflective layer RL1 and the connection line 130 are separated so as not to be connected and the defect that the first connection electrode CE1 and the connection line 130 are connected to the second connection electrode CE2 through the first reflective layer RL1 can be suppressed.

The light conversion layer CCL is disposed in the second groove 149b of the second planarization layer 149. The second groove 149b and the light conversion layer CCL can be disposed on the first line pattern 122 and the connection line 130. The light conversion layer CCL is disposed in an area of the first light emitting diode 150 in a lateral direction on the first line pattern 122 to convert light from the first light emitting diode 150 into red light.

Next, the second connection electrode CE2 is disposed on the second planarization layer 149. The second connection electrodes CE2 extends from the first plate pattern 121 to the first line pattern 122 to be electrically connected to the first p-type electrode 155 of the first light emitting diode 150. At this time, at least a part of the second connection electrode CE2 is disposed in the first groove 149a to be in contact with the first reflective layer RL1.

Accordingly, in a display device 100 according to still another example embodiment of the present disclosure, the first light emitting diode 150 of the first sub pixel SP1 and the light conversion layer CCL can be disposed on the first line pattern 122. The first light emitting diode 150 and the light conversion layer CCL are disposed on the first line pattern 122 to display red light. The first line pattern 122 extends long in the first direction D1 or the second direction D2 and the light conversion layer CCL having a long length can be more easily formed on the first line pattern 122.

The example embodiments of the present disclosure can also be described as follows:

According to an aspect of the present disclosure, a display device includes a lower substrate which includes a plurality of rigid areas disposed to be spaced apart from each other and a malleable area enclosing the plurality of rigid areas, a plurality of first plate patterns disposed in the plurality of rigid areas of the lower substrate, and a plurality of first sub pixels which is partially disposed on the plurality of first plate patterns, and each of the plurality of first sub pixels includes a first light emitting diode, a light conversion layer facing one side surface of the first light emitting diode, and a first reflective layer facing an opposite surface of one side surface of the first light emitting diode.

The first reflective layer, the first light emitting diode, and the light conversion layer can be disposed on one line and the first light emitting diode can be disposed between the light conversion layer and the first reflective layer.

The first light emitting diode can include a first emission layer, and one pair of electrodes disposed on and below the first emission layer, and an electrode disposed on the first light emitting layer, between the one pair of electrodes, can be an opaque electrode.

The display device can further include a first planarization layer disposed below the first light emitting diode, and a second planarization layer disposed on the first planarization layer and the first light emitting diode, and the second planarization layer can include a first groove which has the first reflective layer disposed therein and is disposed to be spaced apart from the first light emitting diode, and a second groove which has the light conversion layer disposed therein.

The display device can further include a second reflective layer disposed between the second groove and the light conversion layer, and the second reflective layer can be disposed in a remaining part, among a plurality of inner surfaces of the second groove, excluding an inner surface of the second groove facing the first light emitting diode.

The first reflective layer, the first light emitting diode, and the light conversion layer of each of the plurality of first sub pixels can be disposed on the plurality of first plate patterns.

Each of the plurality of first plate patterns can include a protrusion protruding to the malleable area and at least a part of each of the plurality of first sub pixels can be disposed on the protrusion.

The first light emitting diode and the first reflective layer can be disposed on the plurality of first plate patterns and the light conversion layer can be disposed on the protrusion.

The first planarization layer and the second planarization layer can be disposed to extend from the plurality of first plate patterns to the protrusion.

The display device can further include a plurality of first line patterns disposed between the plurality of first plate patterns in the malleable area, and at least a part of each of the plurality of first sub pixels can be disposed on the plurality of first line patterns.

The first light emitting diode and the first reflective layer can be disposed on the plurality of first plate patterns and the light conversion layer can be disposed on the plurality of first line patterns.

The first planarization layer and the second planarization layer can be disposed to extend from the plurality of first plate patterns to a partial area of the plurality of first line patterns which overlaps the light conversion layer.

The first light emitting diode, the first reflective layer, and the light conversion layer can be disposed on the plurality of first line patterns.

The first planarization layer and the second planarization layer can be disposed to extend from the plurality of first plate patterns to a partial area of the plurality of first line patterns which overlaps the first light emitting diode, the first reflective layer, and the light conversion layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a lower substrate including a plurality of rigid areas disposed to be spaced apart from each other and a malleable area enclosing the plurality of rigid areas;
a plurality of first plate patterns disposed in the plurality of rigid areas of the lower substrate; and
a plurality of first sub pixels partially disposed on the plurality of first plate patterns,
wherein each of the plurality of first sub pixels includes:
a first light emitting diode;
a light conversion layer facing one side surface of the first light emitting diode; and
a first reflective layer facing an opposite surface of one side surface of the first light emitting diode.

2. The display device according to claim 1, wherein the first reflective layer, the first light emitting diode, and the light conversion layer are disposed on one line, and the first light emitting diode is disposed between the light conversion layer and the first reflective layer.

3. The display device according to claim 1, wherein the first light emitting diode includes:
a first emission layer; and
one pair of electrodes disposed on and below the first emission layer, and
wherein an electrode disposed on the first light emitting layer, between the one pair of electrodes, is an opaque electrode.

4. The display device according to claim 1, further comprising:
a first planarization layer disposed below the first light emitting diode; and
a second planarization layer disposed on the first planarization layer and the first light emitting diode, and
wherein the second planarization layer includes:
a first groove having the first reflective layer disposed therein and disposed to be spaced apart from the first light emitting diode; and
a second groove having the light conversion layer disposed therein.

5. The display device according to claim 4, further comprising:
a second reflective layer disposed between the second groove and the light conversion layer,
wherein the second reflective layer is disposed in a remaining part, among a plurality of inner surfaces of the second groove, excluding an inner surface of the second groove facing the first light emitting diode.

6. The display device according to claim 4, wherein the first reflective layer, the first light emitting diode, and the light conversion layer of each of the plurality of first sub pixels are disposed on the plurality of first plate patterns.

7. The display device according to claim 4, wherein each of the plurality of first plate patterns includes a protrusion protruding to the malleable area, and
wherein at least a part of each of the plurality of first sub pixels is disposed on the protrusion.

8. The display device according to claim 7, wherein the first light emitting diode and the first reflective layer are disposed on the plurality of first plate patterns, and the light conversion layer is disposed on the protrusion.

9. The display device according to claim 8, wherein the first planarization layer and the second planarization layer are disposed to extend from the plurality of first plate patterns to the protrusion.

10. The display device according to claim 4, further comprising:
a plurality of first line patterns disposed between the plurality of first plate patterns in the malleable area,
wherein at least a part of each of the plurality of first sub pixels is disposed on the plurality of first line patterns.

11. The display device according to claim 10, wherein the first light emitting diode and the first reflective layer are disposed on the plurality of first plate patterns, and the light conversion layer is disposed on the plurality of first line patterns.

12. The display device according to claim 11, wherein the first planarization layer and the second planarization layer are disposed to extend from the plurality of first plate patterns to a partial area of the plurality of first line patterns which overlaps the light conversion layer.

13. The display device according to claim 10, wherein the first light emitting diode, the first reflective layer, and the light conversion layer are disposed on the plurality of first line patterns.

14. The display device according to claim 13, wherein the first planarization layer and the second planarization layer are disposed to extend from the plurality of first plate patterns to a partial area of the plurality of first line patterns which overlaps the first light emitting diode, the first reflective layer, and the light conversion layer.
